(19) United States
(12) Patent Application Publication
(10) Pub. No.: US 2014/0192499 A1
(43) Pub. Date: Jul. 10, 2014

(54) SEMICONDUCTOR DEVICE AND PRINTED CIRCUIT BOARD

(71) Applicant: Naoki Yasuda, Yokohama-shi (JP)

(72) Inventor: Naoki Yasuda, Yokohama-shi (JP)

(73) Assignee: CANON KABUSHIKI KAISHA, Tokyo (JP)

(21) Appl. No.: 14/237,420

(22) PCT Filed: Sep. 13, 2012
(86) PCT No.: PCT/JP2012/074126

§ 371 Date: Feb. 6, 2014

(30) Foreign Application Priority Data
Sep. 14, 2011 (JP) 2011-200178

(51) Int. Cl. H01L 23/498; H05K 1/11

(52) U.S. Cl. CPC H01L 23/49816; H05K 1/111
USPC 361/772; 257/738

(57) ABSTRACT

Provided is a compact semiconductor device having high joint reliability of multiple first ball electrodes arrayed on one surface of a first interposer. On a surface (233a) of a second interposer (233) facing a first interposer (213), second ball electrodes (235) are arranged at grid points at which multiple first straight lines extending in one direction are intersected with multiple second straight lines extending in a direction different from the multiple first straight lines. Corner grid points closest to the corners of the second interposer (233) are set as non-joint grid points at which the first and second interposers (213, 233) are not joined to each other.

### TECHNICAL FIELD

The present invention relates to a semiconductor device in which interposers each having a semiconductor element mounted thereon are stacked, and a printed circuit board including the semiconductor device.

### BACKGROUND ART

Portable electronic products, such as digital cameras and mobile phones, have become more sophisticated and downsized every year, and a semiconductor device used in those products also has the same direction of the requirements. As the electronic products become sophisticated, the number of electrode terminals of the semiconductor device tends to increase. As the electronic products are downsized, it is also essential to downsize the semiconductor device.

As the structure for realizing those requirements, there is known a semiconductor device having a structure called a ball grid array (BGA) in which ball electrodes made of solder balls are arrayed in a grid. In recent years, a stacked semiconductor device called package-on-package (PoP) has also been developed, in which multiple BGA type semiconductor packages are stacked.

In the stacked semiconductor device, even when the number of electrode terminals increases, the ratio of the mounting area can be reduced by stacking the semiconductor packages. A signal wiring distance is shorter than that in the case where the semiconductor packages are arranged in a plane, and the stacked semiconductor device is therefore suitable for high-speed transmission. Hence, the stacked semiconductor device has a tendency to be employed in a portable electronic product more frequently in the future.

### CITATION LIST

### Patent Literature

PTL 1: Japanese Patent Application Laid-Open No. 2001-068594

### SUMMARY OF INVENTION

### Technical Problem

In order to fulfill the needs for a multi-terminal, compact semiconductor device, however, it is necessary to reduce a pitch between electrode terminals. It is therefore essential to reduce the diameter of solder balls used in BGA or PoP, which reduces the joint area of an electrode terminal portion with respect to a printed wiring board (hereinafter, referred to as motherboard) for mounting a semiconductor device thereon.

In the case where a semiconductor device is mounted on a motherboard, when a semiconductor element generates heat during operation, a stress concentrates on a ball electrode at which the motherboard is joined to an interposer due to a difference in coefficient of thermal expansion between the interposer and the motherboard. In general, the semiconductor device includes a semiconductor element, an interposer, and electrode terminals. Usually, the semiconductor element uses silicon having a coefficient of thermal expansion of about 3 ppm/° C., and the interposer uses a glass epoxy resin having a coefficient of thermal expansion of 10 to 15 ppm/° C.

The stress is repeatedly applied to the ball electrode because of a temperature difference between the operating and non-operating states. The ball electrode may be finally broken, resulting in a joint failure. Therefore, if the joint area of the electrode terminals is reduced in order to reduce the electrode terminal pitch of the BGA, there occurs a problem in that the joint strength is lowered and the joint reliability is deteriorated as compared to conventional one.

As a method of enhancing the joint reliability of the semiconductor device, Patent Literature 1 describes the idea of increasing the external shape of a reinforcing pad. In general, an electrode terminal arranged at the corner of the interposer of the semiconductor device has a largest distance to neutral point (DNP) among an arrayed electrode terminal group, and is thus applied with a large stress caused by a difference in coefficient of thermal expansion. The corner of the interposer is therefore a site where a joint failure is apt to occur. As a countermeasure, the reinforcing pad having a large area has heretofore been arranged at the corner of the interposer where a largest stress may be applied, to thereby alleviate stress concentration.

In the semiconductor device having a PoP structure, however, by operating heat of the semiconductor element, a strain occurs in a first interposer joined on the motherboard via multiple first ball electrodes and also in a second interposer joined on the first interposer via multiple second ball electrodes. A stress caused by the strain of the second interposer is therefore applied to the first ball electrodes via the second ball electrodes and the first interposer. Thus, the influence of the second interposer on the joint reliability between the first interposer and the motherboard needs to be taken into account.

By the way, in the semiconductor device having a PoP structure, the ball electrodes are downsized and the pitch between the ball electrodes is narrowed as much as possible, to thereby downsize the semiconductor device as a whole. On the other hand, the increased area of the reinforcing pad for enhancing the joint strength as in the conventional case is disadvantageous for the downsizing of the semiconductor device, which has been a problem.

### Solution to Problem

It is therefore an object of the present invention to provide a compact semiconductor device having high joint reliability of multiple first ball electrodes arrayed on one surface of a first interposer, and provide a printed circuit board including the semiconductor device.

A semiconductor device, comprising: a first interposer on which a first semiconductor element is mounted; multiple first ball electrodes, which are arrayed at grid points of matrix on one surface of the first interposer; a second interposer on which a second semiconductor element is mounted, the second interposer being stacked on the first interposer; and multiple second ball electrodes, which are arrayed at grid points of matrix on a surface of the second interposer facing the first interposer, for joining the second interposer to the first interposer, wherein, the first interposer and the second interposer are not joined to each other at a corner grid point closest to a corner of the second interposer.

### Advantageous Effects of Invention

According to the present invention, even when a strain occurs in the second interposer by operating heat of each semiconductor element, a strain of the first interposer caused by the strain of the second interposer can be suppressed. In this manner, a stress applied to the first ball electrodes close to the corners of the first interposer can be reduced, and hence the joint reliability of the first ball electrodes can be improved. Besides, there is no need to increase the size of each ball electrode in order to enhance the joint strength, and hence a compact semiconductor device can be realized.

Further features of the present invention will become apparent from the following description of exemplary embodiments with reference to the attached drawings.

### BRIEF DESCRIPTION OF DRAWINGS

FIG. 1 is a side view illustrating a schematic configuration of a printed circuit board according to a first embodiment of the present invention.

FIG. 2A is a plan view illustrating an arrangement relationship of second ball electrodes.

FIG. 2B is a plan view illustrating an arrangement relationship of first ball electrodes.

FIG. 2C is a plan view illustrating an arrangement relationship of the first and second ball electrodes.

FIG. 3A is a conceptual view illustrating a non-joined state at a corner grid point.

FIG. 3B is a conceptual view illustrating a non-joined state at a corner grid point.

FIG. 4A is an explanatory view illustrating an enlarged main portion of interposers.

FIG. 4B is an explanatory view illustrating an enlarged main portion of interposers.

FIG. 5A is a conceptual view illustrating an arrangement relationship of second ball electrodes with respect to first ball electrodes.

FIG. 5B is a conceptual view illustrating an arrangement relationship of the second ball electrodes with respect to the first ball electrodes.

FIG. 5C is a conceptual view illustrating an arrangement relationship of the second ball electrodes with respect to the first ball electrodes.

FIG. 6A is a conceptual view illustrating an arrangement relationship of first ball electrodes of a semiconductor device according to a second embodiment of the present invention.

FIG. 6B is a conceptual view illustrating an arrangement relationship of first and second ball electrodes of the semiconductor device according to the second embodiment of the present invention.

FIG. 7A is a conceptual view illustrating an arrangement relationship of first ball electrodes of a semiconductor device according to a third embodiment of the present invention.

FIG. 7B is a conceptual view illustrating an arrangement relationship of first and second ball electrodes of the semiconductor device according to the third embodiment of the present invention.

### DESCRIPTION OF EMBODIMENTS

Hereinafter, embodiments of the present invention are described in detail with reference to the accompanying drawings.

### First Embodiment

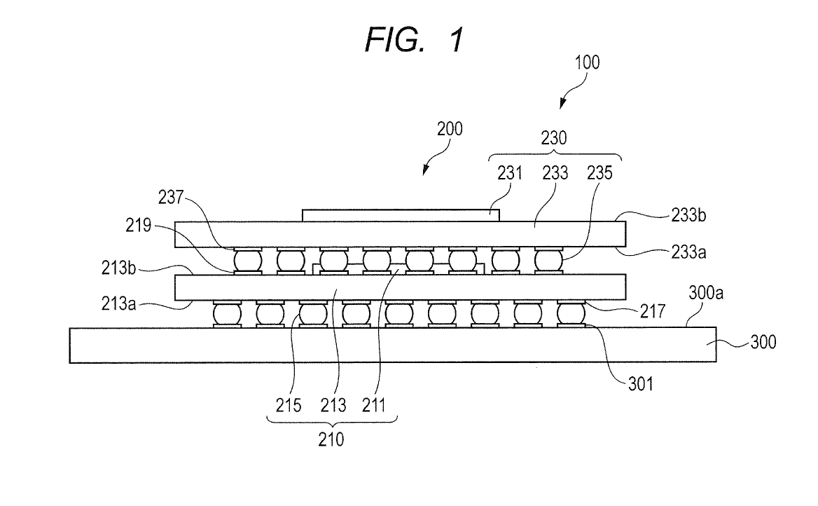

FIG. 1 is a side view illustrating a schematic configuration of a printed circuit board including a semiconductor device according to a first embodiment of the present invention. A printed circuit board 100 includes a semiconductor device 200 and a printed wiring board (hereinafter, referred to as motherboard) 300 on which the semiconductor device 200 is mounted.

The semiconductor device 200 has a so-called package-on-package (PoP) structure in which a first semiconductor package 210 and a second semiconductor package 230 are stacked.

The first semiconductor package 210 includes a first semiconductor element 211, a first interposer 213, and multiple first ball electrodes 215 made of solder balls. The second semiconductor package 230 includes a second semiconductor element 231, a second interposer 233, and multiple second ball electrodes 235 made of solder balls. The multiple second ball electrodes 235 are arrayed at grid points of matrix on a surface of the second interposer 233.

One surface 213a of the first interposer 213 faces the motherboard 300. On the one surface 213a, the multiple first ball electrodes 215 are arrayed at intervals. Specifically, multiple electrode pads 217 are formed on the one surface 213a of the first interposer 213, and the first ball electrodes 215 are joined on the electrode pads 217. The multiple first ball electrodes 215 are arrayed at grid points of matrix on one surface of the first interposer 213.

On a surface 300a of the motherboard 300, multiple electrode pads 301 are formed at positions corresponding to the first ball electrodes 215. The first ball electrodes 215 are joined on the electrode pads 301 formed on the surface 300a of the motherboard 300. In this manner, the first interposer 213 is electrically and mechanically joined to the motherboard 300 via the first ball electrodes 215.

The first semiconductor element 211 is, for example, a logic element (CPU), and is mounted on the other surface 213b of the first interposer 213.

The second interposer 233 is stacked on the first interposer through the intermediation of the second ball electrodes 235. One surface 233a of the second interposer 233 faces the first interposer 213. On the one surface 233a, the multiple second ball electrodes 235 are arrayed at intervals. Specifically, multiple electrode pads 237 are formed on the one surface 233a of the second interposer 233, and the second ball electrodes 235 are joined on the electrode pads 237.

On the other surface 213b of the first interposer 213, multiple electrode pads 219 are formed at positions corresponding to the second ball electrodes 235. The second ball electrodes 235 are joined on the electrode pads 219 formed on the other surface 213b of the first interposer 213. In this manner, the second interposer 233 is electrically and mechanically joined to the first interposer 213 via the second ball electrodes 235.

The second semiconductor element 231 is, for example, a memory element, and is mounted on the other surface 233b of the second interposer 233.

In the first embodiment, the first interposer 213 and the second interposer 233 are formed into a rectangular shape, more specifically, a square shape. The first interposer 213 and the second interposer 233 are formed on the same area and have the same external shape.

Hereinafter, a specific example of each dimension is described. The first semiconductor element 211 has a square shape having one side of about 5 to 8 mm and a thickness of 0.1 to 0.2 mm. The first interposer 213 has a square shape having one side of about 10 to 15 mm and a thickness of 0.5 to 0.8 mm. The solder ball diameter of each first ball electrode 215 is φ0.25 to φ0.4 mm. The diameter of each of the electrode pads 217 and 219 is φ0.2 to φ0.3 mm. The pitch between adjacent two of the first ball electrodes 215 is 0.3 to 0.5 mm.

The second semiconductor element 231 has a square shape having one side of about 5 to 8 mm and a thickness of 0.1 to 0.2 mm. The second interposer 233 has a square shape having one side of about 10 to 15 mm and a thickness of 0.5 to 0.8 mm. The solder ball diameter of each second ball electrode 235 is φ0.25 to φ0.4 mm. The pitch between adjacent two of the second ball electrodes 235 is 0.3 to 0.5 mm.

The external shape of the semiconductor device 200 has a height of 1 to 2 mm.

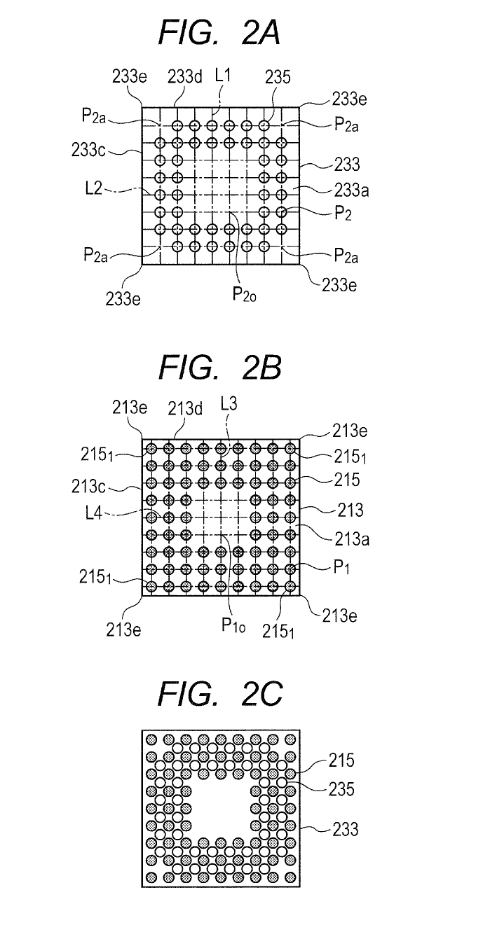

FIGS. 2A to 2C are views illustrating an arrangement relationship of the first and second ball electrodes 215 and 235. FIG. 2A illustrates the arrangement of the second ball electrodes 235. FIG. 2B illustrates the arrangement of the first ball electrodes 215. FIG. 2C illustrates the arrangement of the ball electrodes 215 and 235 when the first ball electrodes 215 are projected on the second interposer 233. In FIGS. 2A to 2C, the first ball electrodes 215 are represented by “black circles” and the second ball electrodes 235 are represented by “white circles”.

As illustrated in FIG. 2A, on the one surface 233a of the second interposer 233, the intersections of multiple first straight lines L1 extending in one direction and multiple second straight lines L2 extending in a direction different from the first straight lines L1 are set as grid points P₂ at which the second ball electrodes 235 can be arranged. In the first embodiment, eight straight lines L1 and eight straight lines L2 are provided so as to have eight rows×eight columns.

In the first embodiment, the first straight lines L1 extend in parallel to one side edge 233c of the second interposer 233 and are arranged at equal intervals in the extending direction of a side edge 233d orthogonal to the side edge 233c. The second straight lines L2 extend in a direction orthogonal to the first straight lines L1 and are arranged at equal intervals in the extending direction of the side edge 233c.

The second ball electrodes 235 are arranged at the grid points P₂ in an array. In this case, the second ball electrode 235 is not arranged at grid points (center grid points) P₂ₒ at positions corresponding to the first semiconductor element 211, and is not arranged at grid points (corner grid points) P₂ₐ closest to corners 233e of the second interposer 233. In other words, the second ball electrodes 235 are arranged at the grid points P₂ excluding the center grid points P₂ₒ and the corner grid points P₂ₐ.

That is, the center grid points P₂ₒ and the corner grid points P₂ₐ are set as non-joint grid points at which the first and second interposers 213 and 233 are not joined to each other.

As illustrated in FIG. 2B, on the one surface 213a of the first interposer 213, the intersections of multiple third straight lines L3 extending in one direction and multiple fourth straight lines L4 extending in a direction different from the third straight lines L3 are set as grid points P₁ at which the first ball electrodes 215 can be arranged. In the first embodiment, nine straight lines L3 and nine straight lines L4 are provided so as to have nine rows×nine columns.

In the first embodiment, the third straight lines L3 extend in parallel to one side edge 213c of the first interposer 213 and are arranged at equal intervals in the extending direction of a side edge 213d orthogonal to the side edge 213c. The fourth straight lines L4 extend in a direction orthogonal to the third straight lines L3 and are arranged at equal intervals in the extending direction of the side edge 213c.

The first ball electrodes 215 are arranged at the grid points P₁ in an array. A necessary number of the first ball electrodes 215 are arranged sequentially from the grid point P₁ positioned at the outermost circumference toward the inner circumference. The remaining center grid points P₁ₒ are non-joint grid points. Dummy ball electrodes may be arranged at the center grid points P₁ₒ so that the first interposer 213 is mechanically joined to the motherboard 300. From the above-mentioned arrangement configuration, the arrangement relationship of the first and second ball electrodes 215 and 235 is as illustrated in FIG. 2C.

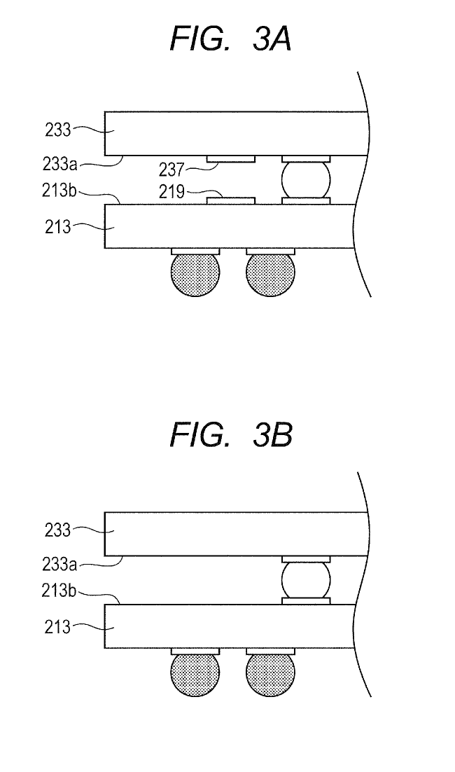

The non-joint grid points refer to, for example, a grid point at which the interposers 213 and 233 are not jointed via the ball electrode even though the electrode pads 219 and 237 are respectively provided on the interposers 213 and 233 as illustrated in FIG. 3A, and a grid point at which the electrode pad and the ball electrode are not provided as illustrated in FIG. 3B.

The reason why the center grid points P₂ₒ on the one surface 233a of the second interposer 233 are set as the non-joint grid points is that the first semiconductor element 211 is present at the positions opposing the center grid points P₂ₒ.

The reason why the corner grid points P₂ₐ on the one surface 233a are set as the non-joint grid points is that the vicinities of the four corners 233e of the second interposer 233 are greatly strained when the second interposer 233 thermally expands by heat generation of the semiconductor elements 231 and 211.

As described above, the second ball electrodes 235 are arranged at the grid points P₂ excluding the corner grid points P₂ₐ, and hence, even when a strain occurs in the second interposer 233, a strain of the first interposer 213 caused by the strain of the second interposer 233 can be suppressed. In this manner, a stress applied to first ball electrodes 215₁ close to corners 213e of the first interposer 213 can be reduced, and hence the joint reliability of the first ball electrodes 215 can be improved. Besides, there is no need to increase the size of each of the ball electrodes 235 and 215, particularly the first ball electrodes 215₁, in order to enhance the joint strength, and hence a compact semiconductor device 200 can be realized.

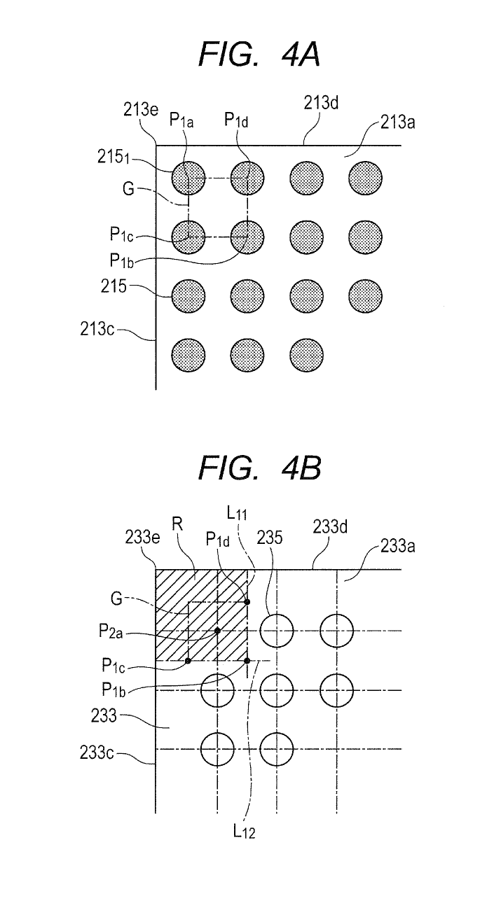

Hereinafter, the arrangement relationship of the ball electrodes 215 and 235 are described more specifically. FIGS. 4A and 4B are explanatory views each illustrating an enlarged main portion of the interposers 213 and 233.

In the first embodiment, as illustrated in FIG. 4A, the first ball electrodes 215 are arranged on the one surface 213a of the first interposer 213 in an array. The edge of a unit grid G including the first ball electrode 215₁ closest to the corner 213e of the first interposer 213 is formed by connecting four grid points P₁ₐ to P_{1d}. As illustrated in FIG. 4B, among the four grid points P₁ₐ to P_{1d}, three grid points P_{1b} to P_{1d} excluding the grid point P₁ₐ closest to the corner 213e of the first interposer 213 are virtually projected on the one surface 233a of the second interposer 233. Two straight lines L11 and L12 passing through the projection point P_{1b} farthest from the corner 233e of the second interposer 233 among the three projection points P_{1b} to P_{1d} and through the remaining two projection points P_{1c} and P_{1d}, respectively, are drawn. Then, a surrounded region R is defined, which is surrounded by the two straight lines L11 and L12 and two side edges 233c and 233d which are intersected with each other at the corner 233e of the second interposer 233.

The surrounded region R is set so that the corner grid point P2a as a non-joint grid point may be arranged in the surrounded region R. That is, in the first embodiment, a shift between the outermost circumference of the multiple first ball electrodes (first ball electrode group) 215 and the outermost circumference of the multiple second ball electrodes (second ball electrode group) 235 is set within 1 pitch. In this case, the corner grid point P₁ₐ and the corner grid point P₂ₐ are close to each other. If the second ball electrode is arranged at the corner grid point P₂ₐ, a large stress acts on the first ball electrode 215₁ arranged at the corner grid point P₁ₐ due to a strain of a corner region of the second interposer 233.

The surrounded region R is a corner region of the second interposer 233. In the first embodiment, the corner grid point P₂ₐ is included in the surrounded region R. The corner grid point P₂ₐ included in the surrounded region R is set as a non-joint grid point, and hence a strain in the vicinity of the corner of the first interposer 213 caused by a strain of the second interposer 233 can be suppressed more effectively. Therefore, the joint reliability of the first ball electrodes 215, particularly the first ball electrode 215₁, can be improved more.

Next, description is given of the results of an experiment which compared the case where four corner grid points P₂ₐ were set as non-joint grid points and the first and second interposers 213 and 233 were not jointed to each other (hereinafter, referred to as non-four-corner joint) and the case where the ball electrodes were arranged at the four corner grid points P₂ₐ and the first and second interposers 213 and 233 were jointed to each other (hereinafter, referred to as four-corner joint) as a comparative example.

Table 1 shows the results of the cumulative failure rate under a temperature cycle test based on the presence or absence of a four-corner joint.

TABLE 1

| | Cycles | | | | | | | | | |
|---|---|---|---|---|---|---|---|---|---|---|
| | 100 | 200 | 300 | 400 | 500 | 600 | 700 | 800 | 900 | 1,000 |
| Four- | 0% | 0% | 0% | 10% | 30% | 60% | 70% | 80% | 100% | — |
| corner | | | | | | | | | | |
| joint | | | | | | | | | | |
| Non- | 0% | 0% | 0% | 0% | 0% | 10% | 10% | 10% | 10% | 20% |
| four- | | | | | | | | | | |
| corner | | | | | | | | | | |
| joint | | | | | | | | | | |

It is confirmed from the results that a defect occurred in a four-corner joint product at 100% after 900 cycles while a defect occurred in a non-four-corner joint product as less frequently as at 20% even after 1,000 cycles, and the non-four-corner joint had high joint reliability.

Next, structural simulation was performed to examine the influence on a stress applied to the first ball electrode 215₁ caused by the positional relationship of the first and second ball electrodes 215 and 235 and by whether the joint was a four-corner joint or a non-four-corner joint. As a simulation model, the first semiconductor element 211 had a square shape having one side of 6 mm and a thickness of 0.1 mm, the first interposer 213 had a square shape having one side of 10 mm and a thickness of 0.55 mm, the first ball electrodes 215 had a solder ball diameter of φ0.3 mm, and the pitch between adjacent two of the first ball electrodes 215 was 0.5 mm. The second semiconductor element 231 had a square shape having one side of 8 mm and a thickness of 0.1 mm, the second interposer 233 had a square shape having one side of 10 mm and a thickness of 0.15 mm, the second ball electrodes 235 had a solder ball diameter of φ0.3 mm, and the pitch between adjacent two of the second ball electrodes 235 was 0.5 mm. The motherboard 300 had a square shape having one side of 30 mm and a thickness of 0.8 mm.

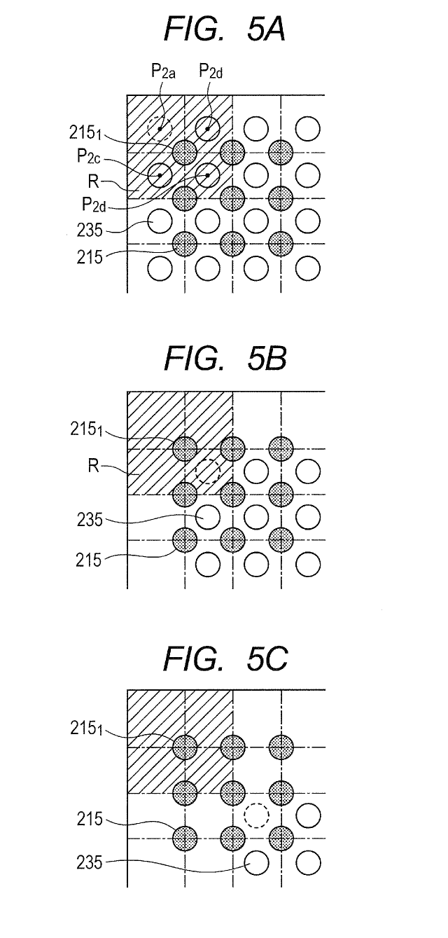

FIGS. 5A to 5C illustrate the structural simulation conditions, illustrating the positional relationship of the first ball electrodes 215 and the second ball electrodes 235 at the four corners. The “black circles” represent the first ball electrodes 215, the “white circles” represent the second ball electrodes 235, and the hatched regions represent the surrounded regions R.

FIG. 5A illustrates the case (A) where the outer circumference of the multiple second ball electrodes (second ball electrode group) 235 is shifted by a half pitch outward from the outer circumference of the multiple first ball electrodes (first ball electrode group) 215. FIG. 5B illustrates the case (B) where the outer circumference of the multiple second ball electrodes (second ball electrode group) 235 is shifted by a half pitch inward from the outer circumference of the multiple first ball electrodes (first ball electrode group) 215. FIG. 5C illustrates the case (C) where the outer circumference of the multiple second ball electrodes (second ball electrode group) 235 is shifted by a 1.5 pitch inward from the outer circumference of the multiple first ball electrodes (first ball electrode group) 215.

Specifically, in the state A of FIG. 5A, the second ball electrodes 235 are positioned outward (to the upper left) from the first ball electrodes 215 by 0.25 mm each in the horizontal and vertical directions of FIG. 5A. In the state B of FIG. 5B, the second ball electrodes 235 are positioned inward (to the lower right) from the first ball electrodes 215 by 0.25 mm each in the horizontal and vertical directions of FIG. 5B. In the state C of FIG. 5C, the second ball electrodes 235 are positioned further inward (to the lower right) from the state B of FIG. 5B by 0.5 mm. In FIGS. 5A to 5C, dotted white circles represent the state in which the second ball electrode 235 is arranged as a comparative example.

Table 2 shows the results of structural simulation under the above-mentioned conditions, showing the values of a stress applied to the first ball electrode 215₁ and a change ratio thereof in the case of the four-corner joint and the non-four-corner joint.

TABLE 2

| Ball electrode | | | |
|---|---|---|---|
| positional relationship | A | B | C |
| Four-corner joint | 102[MPa] | 62[MPa] | 46[MPa] |
| Non-four-corner joint | 71[MPa] | 47[MPa] | 43[MPa] |
| Stress change ratio | −30% | −24% | −5% |

The stress change ratio in the state A was −30%, which was the lowest. The stress change ratio in the state B was −24%, and the stress change ratio in the state C was −5%.

It can be said that the joint reliability becomes higher as the absolute value of the stress change ratio becomes larger. It was therefore confirmed that, in the case where the corner grid point P₂ₐ was positioned in the surrounded region R, the joint reliability was enhanced more effectively by setting the corner grid point P₂ₐ as a non-joint grid point.

By the way, in FIG. 5A, grid points P_{2b} to P_{2d}, which are included in the surrounded region R and adjacent to the corner grid point P₂ₐ, may be set as non-joint grid points. Therefore, at least one of the grid points P_{2b} to P_{2d} which are included in the surrounded region R and adjacent to the corner grid point P₂ₐ may be set as an additional non-joint grid point. In this manner, a stress that acts on the first ball electrode 215₁ can be reduced still more effectively.

Note that, in the above description, the first ball electrodes 215 are arranged in nine rows×nine columns and the second ball electrodes 235 are arranged in eight rows×eight columns, but the present invention is not limited thereto. The arrangement, the array, and the pitch of the ball electrodes are optional.

### Second Embodiment

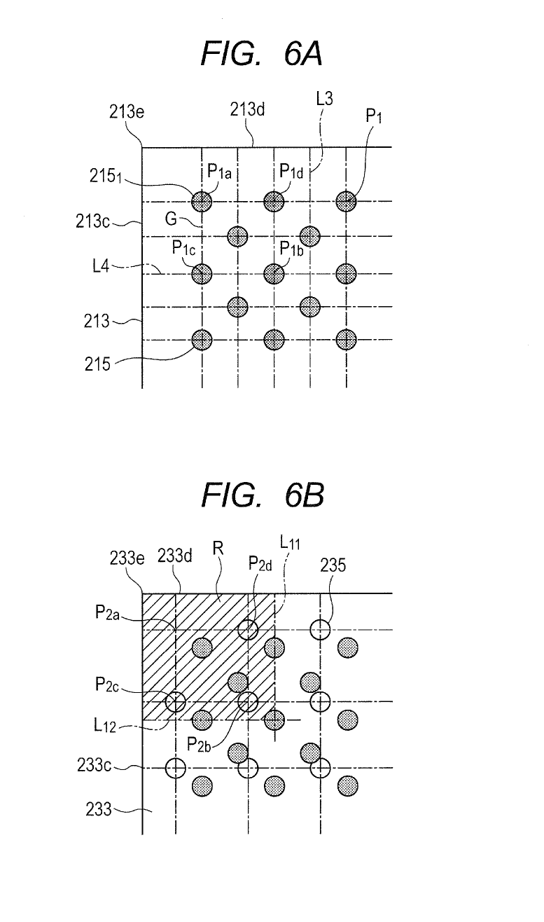

Next, a semiconductor device according to a second embodiment of the present invention is described. The semiconductor device in the second embodiment is different from the semiconductor device in the first embodiment in the arrangement of the first ball electrodes. FIGS. 6A and 6B are views illustrating an arrangement relationship of the first and second ball electrodes 215 and 235 of the semiconductor device according to the second embodiment of the present invention. FIG. 6A illustrates the arrangement of the first ball electrodes 215. FIG. 6B illustrates the arrangement of the ball electrodes 215 and 235 when the first ball electrodes 215 are projected on the second interposer 233. In FIGS. 6A and 6B, the same configurations as in the first embodiment are denoted by the same reference symbols. The first ball electrodes 215 are represented by “black circles” and the second ball electrodes 235 are represented by “white circles”.

In the second embodiment, as illustrated in FIG. 6A, the first ball electrodes 215 are arranged on the one surface 213a of the first interposer 213 in a staggered manner. The edge of a unit grid G including the first ball electrode 215₁ closest to the corner 213e of the first interposer 213 is formed by connecting four grid points P₁ₐ to P_{1d}. As illustrated in FIG. 6B, among the four grid points P₁ₐ to P_{1d}, three grid points P_{1b} to P_{1d} excluding the grid point P₁ₐ closest to the corner 213e of the first interposer 213 are virtually projected on the one surface 233a of the second interposer 233. Two straight lines L11 and L12 passing through the projection point P_{1b} farthest from the corner 233e of the second interposer 233 among the three projection points P_{1b} to P_{1d} and through the remaining two projection points P_{1c} and P_{1d}, respectively, are drawn. Then, a surrounded region R is defined, which is surrounded by the two straight lines L11 and L12 and two side edges 233c and 233d which are intersected with each other at the corner 233e of the second interposer 233.

The surrounded region R is set so that the corner grid point P2a as a non-joint grid point may be arranged in the surrounded region R. That is, a shift between the outermost circumference of the multiple first ball electrodes (first ball electrode group) 215 and the outermost circumference of the multiple second ball electrodes (second ball electrode group) 235 is set within 1 pitch.

Also in the second embodiment, the corner grid points P₂ₐ are set as non-joint grid points at which the first interposer 213 and the second interposer 233 are not joined. Therefore, even when a strain occurs in the second interposer 233, a strain of the first interposer 213 caused by the strain of the second interposer 233 can be suppressed. In this manner, a stress applied to the first ball electrodes 215₁ close to the corners 213e of the first interposer 213 can be reduced, and hence the joint reliability of the first ball electrodes 215 can be improved. Besides, there is no need to increase the size of each of the ball electrodes 235 and 215, particularly the first ball electrode 215₁, in order to enhance the joint strength, and hence a compact semiconductor device 200 can be realized.

In addition, in the second embodiment, the corner grid point P₂ₐ is included in the surrounded region R, and hence a stress applied to the first ball electrode 215₁ can be reduced more effectively.

The grid points P_{2b} to P_{2d}, which are included in the surrounded region R and adjacent to the corner grid point P₂ₐ, may be set as non-joint grid points. That is, at least one of the grid points P_{2b} to P_{2d} may be set as a non-joint grid point. In this manner, a stress applied to the first ball electrode 215₁ can be reduced more effectively.

The following is the results of structural simulation performed in the second embodiment in order to examine the influence on a stress applied to the first ball electrode 215₁ by whether a four-corner joint by the second ball electrodes was provided or not. As a simulation model, the first ball electrodes were arranged in a staggered manner at a pitch of 0.25 mm.

Table 3 shows the results of structural simulation under the above-mentioned condition, showing the values of a stress applied to the first ball electrodes and a change ratio thereof.

TABLE 3

| Ball electrode | Arranged in |
|---|---|
| positional relationship | staggered manner |
| Four-corner joint | 103[MPa] |
| Non-four-corner joint | 96[MPa] |
| Stress change ratio | −7% |

The results show that a stress in the case of the four-corner joint was 103 MPa and a stress in the case of the non-four-corner joint was 96 MPa, and the stress change ratio was −7%. Thus, the improvement in joint reliability was confirmed.

### Third Embodiment

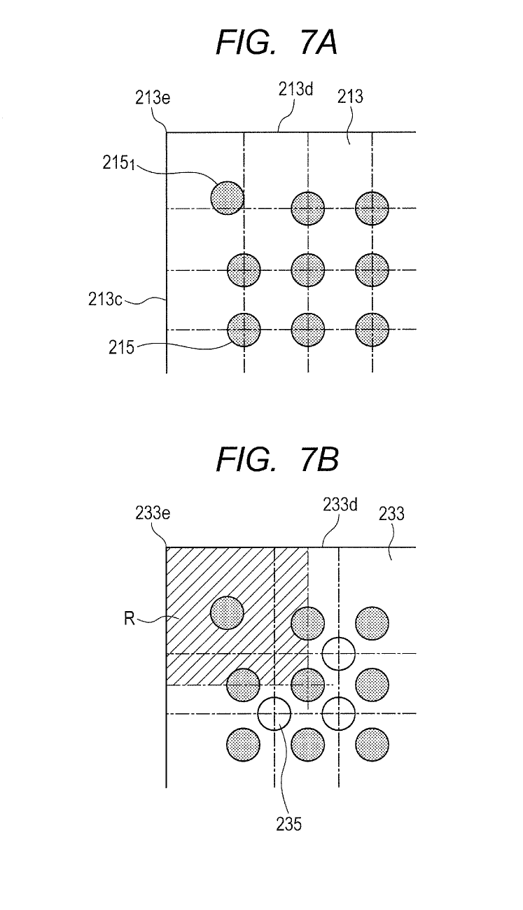

A semiconductor device according to a third embodiment of the present invention is described. FIGS. 7A and 7B are views illustrating an arrangement relationship of the first and second ball electrodes 215 and 235 of the semiconductor device according to the third embodiment of the present invention. FIG. 7A illustrates the arrangement of the first ball electrodes 215. FIG. 7B illustrates the arrangement of the first and second ball electrodes 215 and 235 when the first ball electrodes 215 are projected on the second interposer 233. In FIGS. 7A and 7B, the first ball electrodes 215 are represented by “black circles” and the second ball electrodes 235 are represented by “white circles”.

As illustrated in FIG. 7A, a part of the ball electrodes 215, for example, the first ball electrode 215₁ closest to the corner 213e of the first interposer 213, may be deviated from a grid point.

Also in this case, the first and second interposers 213 and 233 are not jointed to each other via the second ball electrode 235 in the surrounded region R of the second interposer 233 illustrated in FIG. 7B. In this manner, the influence of a stress of the second interposer 233 on the first interposer 213 can be reduced, and hence a stress applied to the first ball electrodes 215 can be alleviated. Therefore, the effect of improving the joint reliability can be obtained.

The following is the results of structural simulation performed in the third embodiment in order to examine the influence on a stress applied to the first ball electrode 215₁ by whether a four-corner joint by the second ball electrodes was provided or not. As a simulation model, the first ball electrodes 215₁ were positioned deviating from the grid point by 0.5 mm.

Table 4 shows the results of structural simulation under the above-mentioned condition, showing the values of a stress applied to the first ball electrodes 215₁ and a change ratio thereof.

TABLE 4

| Ball electrode | Arranged off |
|---|---|
| positional relationship | grid point |
| Four-corner joint | 65[MPa] |
| Non-four-corner joint | 57[MPa] |
| Stress change ratio | −13% |

The results show that a stress in the case of the four-corner joint was 65 MPa and a stress in the case of the non-four-corner joint was 57 MPa, and the stress change ratio was −13%. Thus, the improvement in joint reliability was confirmed.

Note that, the present invention is not limited to the embodiments described above, and various modifications can be made thereto by a person having ordinary skill in the art within the technical idea of the present invention.

In the embodiments, the dimensions of the external shape have been described above, but the values are not limitative. Each ball electrode is a solder ball, but the present invention is not limited thereto. The ball electrode may be a resin ball or a metal ball surrounded by solder.

In the embodiments, all the four corner grid points are set as non-joint grid points, but the configuration is not limited thereto. It is most effective to set all the four corner grid points as non-joint grid points, but not all the corner grid points need to be set as non-joint grid points. It is sufficient that at least one corner grid point be a non-joint grid point.

In the embodiments, the second ball electrodes are arrayed in an array, but may be arrayed in a staggered manner.

In the embodiments, the second semiconductor element is not encapsulated, but may be encapsulated by a resin mold.

In the embodiments, the first straight lines and the second straight lines are orthogonal to each other, but the present invention is not limited to the case where the first straight lines and the second straight lines are orthogonal to each other. It is sufficient that the first straight lines and the second straight lines be intersected with each other. The same holds true for the third and fourth straight lines.

In the embodiments, the first semiconductor element is mounted on the other surface of the first interposer, but may be mounted on the one surface thereof. In the embodiments, the second semiconductor element is mounted on the other surface of the second interposer, but may be mounted on the one surface thereof.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-200178, filed Sep. 14, 2011, which is hereby incorporated by reference herein in its entirety.

1. A semiconductor device, comprising:
a first interposer on which a first semiconductor element is mounted;
multiple first ball electrodes, which are arrayed at grid points of matrix on one surface of the first interposer;
a second interposer on which a second semiconductor element is mounted, the second interposer being stacked on the first interposer; and
multiple second ball electrodes, which are arrayed at grid points of matrix on a surface of the second interposer facing the first interposer, for joining the second interposer to the first interposer,
wherein, the first interposer and the second interposer are not joined to each other at a corner grid point closest to a corner of the second interposer.

2. The semiconductor device according to claim 1, further comprising electrode pads, which are formed at the corner grid point closest to the corner of the second interposer and are formed on a surface of the first interposer facing the corner grid point.

3. A semiconductor device, comprising:
a first interposer on which a first semiconductor element is mounted;
multiple first ball electrodes, which are arrayed at grid points of matrix on one surface of the first interposer;
a second interposer on which a second semiconductor element is mounted, the second interposer being stacked on the first interposer; and
multiple second ball electrodes, which are arrayed at grid points of matrix on a surface of the second interposer facing the first interposer, for joining the second interposer to the first interposer,
wherein, in a case where, among four grid points that form a minimum unit grid of one of the multiple first ball electrodes closest to a corner of the first interposer,
three grid points excluding a grid point closest to the corner of the first interposer are projected on the second interposer,
the first interposer and the second interposer positioned at a grid point in a region surrounded by two straight lines passing through a projection point farthest from a corner of the second interposer closest from the corner of the first interposer among three projection points and through remaining two projection points, respectively, and by two side edges which are intersected with each other at the corner of the second interposer are not connected to second ball electrodes joined to each other.

4. The semiconductor device according to claim 3, further comprising electrode pads, which are formed at the corner grid point closest to the corner of the second interposer and are formed on a surface of the first interposer facing the corner grid point.

5. A printed circuit board, comprising:
a printed wiring board;
a semiconductor device on which the semiconductor device is mounted;
a first interposer on which a first semiconductor element is mounted;
multiple first ball electrodes, which are arrayed at grid points of matrix on one surface of the first interposer and joined to the printed wiring board;
a second interposer on which a second semiconductor element is mounted, the second interposer being stacked on the first interposer; and
multiple second ball electrodes, which are arrayed at grid points of matrix on a surface of the second interposer facing the first interposer, for joining the second interposer to the first interposer,
wherein, the first interposer and the second interposer are not joined to each other at a corner grid point closest to a corner of the second interposer.

6. The printed circuit board according to claim 5, further comprising electrode pads, which are formed at the corner grid point closest to the corner of the second interposer and are formed on a surface of the first interposer facing the corner grid point.

7. A printed circuit board, comprising:
a printed wiring board;
a semiconductor device on which the semiconductor device is mounted;
a first interposer on which a first semiconductor element is mounted;
multiple first ball electrodes, which are arrayed at grid points of matrix on one surface of the first interposer and joined to the printed wiring board;
a second interposer on which a second semiconductor element is mounted, the second interposer being stacked on the first interposer; and
multiple second ball electrodes, which are arrayed at grid points of matrix on a surface of the second interposer facing the first interposer, for joining the second interposer to the first interposer,
wherein, in a case where, among four grid points that form a minimum unit grid of one of the multiple first ball electrodes closest to a corner of the first interposer, three grid points excluding a grid point closest to the corner of the first interposer are projected on the second interposer, the first interposer and the second interposer positioned at a grid point in a region surrounded by two straight lines passing through a projection point farthest from a corner of the second interposer closest from the corner of the first interposer among three projection points and through remaining two projection points, respectively, and by two side edges which are intersected with each other at the corner of the second interposer are not connected to second ball electrodes joined to each other.

8. The printed circuit board according to claim 7, further comprising electrode pads, which are formed at the corner grid point closest to the corner of the second interposer and are formed on a surface of the first interposer facing the corner grid point.
